(19) United States
(12) Patent Application Publication
(10) Pub. No.: US 2015/0371992 A1
(43) Pub. Date: Dec. 24, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventor: Akira HOKAZONO, Kawasaki Kanagawa (JP)

(73) Assignee: KABUSHIKI KAISHA TOSHIBA, Tokyo (JP)

(21) Appl. No.: 14/479,116

(22) Filed: Sep. 5, 2014

(30) Foreign Application Priority Data
Jun. 19, 2014 (JP) 2014-126475

(51) Int. Cl. H01L 27/11; H01L 29/66

(52) U.S. Cl. CPC H01L 27/1104; H01L 29/66477

(57) ABSTRACT

In one embodiment, a semiconductor device includes one or more gate conductors provided above a substrate, and including a pair of first portions adjacent to each other and a pair of second portions adjacent to each other. The device further includes a first diffusion region which is provided in a first region located between the pair of first portions, and corresponds to one of a drain region of a first conductivity type and a source region of a second conductivity type for a first transistor of the first conductivity type. The device further includes a second diffusion region which is provided in a second region located between the pair of second portions, and corresponds to the other of the drain and source regions for the first transistor. A first distance between the pair of first portions is shorter than a second distance between the pair of second portions.

### CROSS REFERENCE TO RELATED APPLICATION

This application is based upon and claims the benefit of priority from the prior Japanese Patent Application No. 2014-126475, filed on Jun. 19, 2014, the entire contents of which are incorporated herein by reference.

### FIELD

Embodiments described herein relate to a semiconductor device and a method of manufacturing the same.

### BACKGROUND

Tunnel FETs (TFETs) are attracting attention as transistors suitable for operating with low power consumption. When a TFET is fabricated, impurities having different conductivity types are implanted into a source region and a drain region of the TFET. Accordingly, lithography is necessary to be performed such that the boundary of a resist mask is formed on a gate electrode of the TFET. Therefore, the shorter the gate length of the gate electrode of the TFET becomes, the higher the precision required for the lithography becomes. Accordingly, reduction of the gate length is restricted by the lithography. However, if the gate length of the TFET is set long, the circuit area of the semiconductor device is increased, and therefore costs for the semiconductor device is increased. Moreover, if the gate length of the TFET is set long, the gate capacity and the junction capacity in the semiconductor device is increased, and therefore power consumption of the semiconductor device cannot be effectively reduced in spite of using the TFET.

### BRIEF DESCRIPTION OF THE DRAWINGS

FIG. 1 is a plan view illustrating a structure of a semiconductor device of a first embodiment;

FIGS. 2A and 2B are cross-sectional views illustrating the structure of the semiconductor device of the first embodiment;

FIGS. 3A to 11B are cross-sectional views illustrating a method of manufacturing the semiconductor device of the first embodiment;

FIGS. 12A to 12C are a circuit diagram, a plan view and a cross-sectional view illustrating a structure of a semiconductor device of a first modification of the first embodiment;

FIGS. 13A to 13C are a circuit diagram, a plan view and a cross-sectional view illustrating a structure of a semiconductor device of a second modification of the first embodiment;

FIGS. 14A and 14B are a plan view and a cross-sectional view illustrating a structure of a semiconductor device of a second embodiment;

FIGS. 15A to 17C are cross-sectional views illustrating a method of manufacturing the semiconductor device of the second embodiment;

FIGS. 18A and 18B are a plan view and a cross-sectional view illustrating a structure of a semiconductor device of a third embodiment; and

FIGS. 19A to 21C are cross-sectional views illustrating a method of manufacturing the semiconductor device of the third embodiment.

### DETAILED DESCRIPTION

Embodiments will now be explained with reference to the accompanying drawings.

In one embodiment, a semiconductor device includes a substrate, and one or more gate conductors provided above the substrate, and including a pair of first portions adjacent to each other and a pair of second portions adjacent to each other. The device further includes a first diffusion region which is provided in a first region located between the pair of first portions, and corresponds to one of a drain region of a first conductivity type and a source region of a second conductivity type for a first transistor of the first conductivity type. The device further includes a second diffusion region which is provided in a second region located between the pair of second portions, and corresponds to the other of the drain and source regions for the first transistor. A first distance between the pair of first portions is shorter than a second distance between the pair of second portions.

### First Embodiment

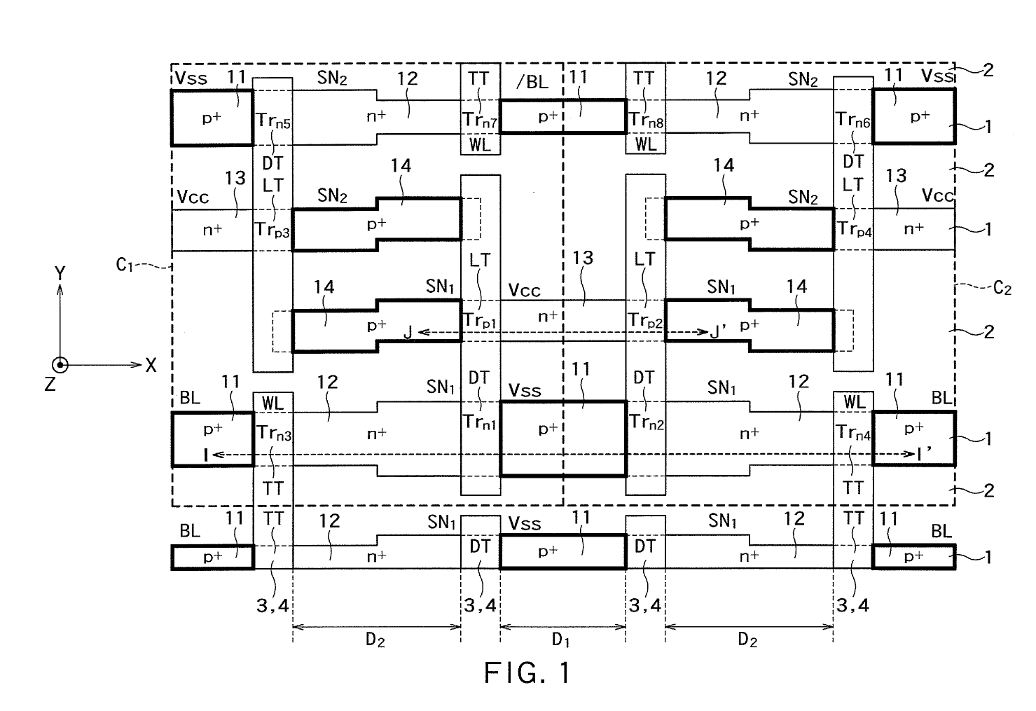

FIG. 1 is a plan view illustrating a structure of a semiconductor device of a first embodiment.

The semiconductor device in FIG. 1 includes a static random access memory (SRAM). FIG. 1 illustrates n-type transistors Trₙ₁ to Trₙ₈ and p-type transistors Trₚ₁ to Trₚ₄ forming the SRAM. One of the n-type and the p-type is an example of a first conductivity type. The other of the n-type and the p-type is an example of a second conductivity type. All of the n-type transistors Trₙ₁ to Trₙ₈ and the p-type transistors Trₚ₁ to Trₚ₄ are TFETs.

Signs LT, DT and TT designate loading transistors, driver transistors and transfer transistors of the SRAM, respectively. Signs C₁ and C₂ designate SRAM cells. The n-type transistors Trₙ₁ and Trₙ₅ are driver transistors DT of the SRAM cell C₁. The n-type transistors Trₙ₃ and Trₙ₇ are transfer transistors TT of the SRAM cell C₁. The p-type transistors Trₚ₁ and Trₚ₃ are loading transistors LT of the SRAM cell C₁. The n-type transistors Trₙ₂ and Trₙ₆ are driver transistors DT of the SRAM cell C₂. The n-type transistors Trₙ₄ and Trₙ₈ are transfer transistors TT of the SRAM cell C₂. The p-type transistors Trₚ₂ and Trₚ₄ are loading transistors LT of the SRAM cell C₂.

The semiconductor device in FIG. 1 includes a substrate 1, isolation regions 2, gate insulators 3, gate conductors 4, first source regions 11 for the n-type transistors Trₙ₁ to Trₙ₈, first drain regions 12 for the n-type transistors Trₙ₁ to Trₙ₈, second source regions 13 for the p-type transistors Trₚ₁ to Trₚ₄, and second drain regions 14 for the p-type transistors Trₚ₁ to Trₚ₄.

The first source regions 11 of the n-type transistors Trₙ₁, Trₙ₂, Trₙ₅ and Trₙ₆ (DT) are supplied with the ground voltage Vss. The second source regions 13 of the p-type transistors Trₚ₁ to Trₚ₄ (LT) are supplied with the power supply voltage Vcc.

The first drain region 12 of the n-type transistors Trₙ₁ and Trₙ₃ (DT, TT) and the second drain region 14 of the p-type transistor Trₚ₁ (LT) are connected to a first storage node SN₁ of the SRAM cell C₁. The first storage node SN₁ of the SRAM cell C₁ is connected to the gate electrodes of the n-type transistor Trₙ₅ and the p-type transistor Trₚ₃. The first drain region 12 of the n-type transistors Trₙ₅ and Trₙ₇ (DT, TT) and the second drain region 14 of the p-type transistor Trₚ₃ (LT) are connected to a second storage node SN₂ of the SRAM cell C₁. The second storage node SN₂ of the SRAM cell C₁ is connected to the gate electrodes of the n-type transistor Trₙ₁ and the p-type transistor Trₚ₁.

The first drain region 12 of the n-type transistors Trₙ₂ and Trₙ₄ (DT, TT) and the second drain region 14 of the p-type transistor Trₚ₂ (LT) are connected to a first storage node SN₁ of the SRAM cell C₂. The first storage node SN₁ of the SRAM cell C₂ is connected to the gate electrodes of the n-type transistor Trₙ₆ and the p-type transistor Trₚ₄. The first drain region 12 of the n-type transistors Trₙ₆ and Trₙ₈ (DT, TT) and the second drain region 14 of the p-type transistor Trₚ₄ (LT) are connected to a second storage node SN₂ of the SRAM cell C₂. The second storage node SN₂ of the SRAM cell C₂ is connected to the gate electrodes of the n-type transistor Trₙ₂ and the p-type transistor Trₚ₂.

The first source regions 11 of the n-type transistors Trₙ₃, Trₙ₄, Trₙ₇ and Trₙ₈ (TT) are connected to bit lines BL and /BL.

Sign WL designates the gate conductors 4 (pass gates) that functions as word lines. The gate electrodes of the n-type transistors Trₙ₃, Trₙ₄, Trₙ₇ and Trₙ₈ (TT) are connected to word lines WL.

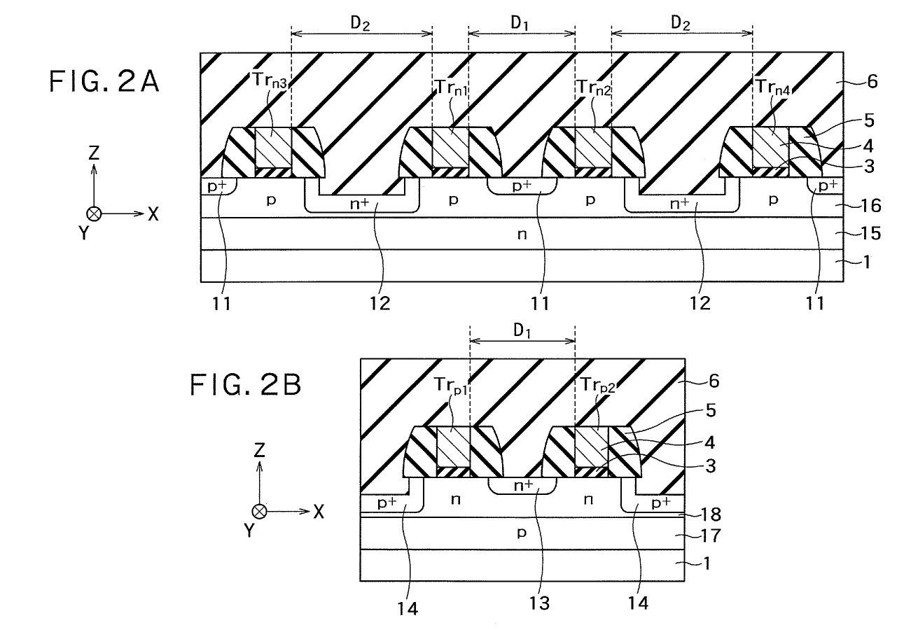

FIGS. 2A and 2B are cross-sectional views illustrating the structure of the semiconductor device of the first embodiment. FIG. 2A illustrates a cross-section taken along the I-I′ line illustrated in FIG. 1. FIG. 2B illustrates a cross-section taken along the J-Y line illustrated in FIG. 1.

The structure of the semiconductor device of the present embodiment will be described in detail with reference to FIGS. 2A and 2B. FIG. 1 is also referred to properly in the following description.

The semiconductor device of the present embodiment includes the substrate 1, the isolation regions 2, the gate insulators 3, the gate conductors 4, sidewall insulators 5, an inter layer dielectric 6, the first source regions 11, the first drain regions 12, the second source regions 13, the second drain regions 14, a first well region 15, a first channel region 16, a second well region 17 and a second channel region 18.

An example of the substrate 1 is a semiconductor substrate such as a silicon substrate. The substrate 1 may be any of a p-type substrate and an n-type substrate. FIGS. 2A and 2B illustrate an X-direction and a Y-direction which are parallel to the surface of the substrate 1 and perpendicular to each other, and a Z-direction perpendicular to the surface of the substrate 1. In this specification, the +Z-direction is regarded as an upward direction and the −Z-direction is regarded as a downward direction. For example, positional relation between the substrate 1 and the gate conductors 4 is expressed as that the substrate 1 is located below the gate conductors 4.

The isolation regions 2 are formed on the surface of the substrate 1 (refer to FIG. 1). An example of the isolation regions 2 is insulators such as silicon oxide films.

Each of the n-type transistors Trₙ₁ to Trₙ₈ and the p-type transistors Trₚ₁ to Trₚ₄ (hereinafter, referred to as each transistor) includes a gate insulator 3, a gate conductor 4 and sidewall insulators 5.

The gate insulator 3 is formed on the substrate 1. Examples of the gate insulator 3 are a silicon oxide film (SiO₂), a silicon nitride film (SiN), a silicon oxynitride film (SiON), a high-k film and the like. An example of the high-k film is a HfSiON film.

The gate conductor 4 is formed on the substrate 1 via the gate insulator 3. Examples of the gate conductor 4 are a polysilicon layer and a metal layer. The gate conductors 4 of the present embodiment extend in the Y-direction and are adjacent to one another in the X-direction (refer to FIG. 1). The gate conductor 4 in each transistor functions as a gate electrode, and the remaining portion of the gate conductor 4 functions as a gate interconnect.

The sidewall insulators 5 are formed on side faces of the gate conductor 4. Examples of the sidewall insulators 5 are silicon nitride films and TEOS films. Each of the sidewall insulators 5 may be a stack film including a silicon nitride film and a TEOS film.

The inter layer dielectric 6 is formed on the substrate 1 so as to cover the n-type transistors Trₙ₁ to Trₙ₈ and the p-type transistors Trₚ₁ to Trₚ₄. An example of the inter layer dielectric 6 is a silicon oxide film.

The first source regions 11 are p⁺-type regions in the substrate 1. Each first source region 11 is formed between the gate conductors 4 adjacent to each other. The first source regions 11 correspond to source regions for the n-type transistors Trₙ₁ to Trₙ₈.

FIG. 2A illustrates the first source region 11 formed between the gate electrode (gate conductor 4) of the n-type transistor Trₙ₁ and the gate electrode (gate conductor 4) of the n-type transistor Trₙ₂. The gate electrodes of the n-type transistors Trₙ₁ and Trₙ₂ are examples of a pair of first portions adjacent to each other included in the gate conductors 4. Moreover, a region in the substrate 1 where the first source region 11 is formed is an example of a first region, and the first source region 11 is an example of a first diffusion region. The n-type transistors Trₙ₁ and Trₙ₂ are examples of a first transistor.

The first drain regions 12 are n⁺-type regions in the substrate 1. Each first drain region 12 is formed between the gate conductors 4 adjacent to each other. The first drain regions 12 correspond to drain regions for the n-type transistors Trₙ₁ to Trₙ₈.

FIG. 2A illustrates the first drain region 12 formed between the gate electrode (gate conductor 4) of the n-type transistor Trₙ₁ and the gate electrode (gate conductor 4) of the n-type transistor Trₙ₃, and the first drain region 12 formed between the gate electrode (gate conductor 4) of the n-type transistor Trₙ₂ and the gate electrode (gate conductor 4) of the n-type transistor Trₙ₄. The gate electrodes of the n-type transistors Trₙ₁ and Trₙ₃ are examples of a pair of second portions adjacent to each other included in the gate conductors 4. Similarly, the gate electrodes of the n-type transistors Trₙ₂ and Trₙ₄ are examples of the pair of second portions. Moreover, regions in the substrate 1 where the first drain regions 12 are formed are examples of a second region, and the first drain regions 12 are examples of a second diffusion region. The n-type transistors Trₙ₃ and Tr₄ are examples of a second transistor.

The second source regions 13 are n⁺-type regions in the substrate 1. Each second source region 13 is formed between the gate conductors 4 adjacent to each other. The second source regions 13 correspond to source regions for the p-type transistors Trₚ₁ to Trₚ₄.

FIG. 2B illustrates the second source region 13 formed between the gate electrode (gate conductor 4) of the p-type transistor Trₚ₁ and the gate electrode (gate conductor 4) of the p-type transistor Trₚ₂. The gate electrodes of the p-type transistors Trₚ₁ and Trₚ₂ are examples of the pair of first portions adjacent to each other included in the gate conductors 4. Moreover, a region in the substrate 1 where the second source region 13 is formed is an example of the first region, and the second source region 13 is an example of the first diffusion region. The p-type transistors Trₚ₁ and Trₚ₂ are examples of the first transistor.

The second drain regions 14 are p⁺-type regions in the substrate 1. Each second drain region 14 is formed between the gate conductors 4 adjacent to each other. The second drain regions 14 correspond to drain regions for the p-type transistors Trₚ₁ to Trₚ₄.

FIG. 1 illustrates examples of the second drain regions 14 each formed between a pair of second portions adjacent to each other included in the gate conductors 4. Regions in the substrate 1 where the second drain regions 14 are formed are examples of the second region, and the second drain regions 14 are examples of the second diffusion region.

The first well region 15 and the first channel region 16 are an n-type region and a p-type region in the substrate 1, respectively. The first well region 15 and the first channel region 16 are formed below the n-type transistors Trₙ₁ to Trₙ₈. The first channel region 16 is in contact with the lower faces of the gate insulators 3, the lower face and the side faces of the first source region 11, and the lower faces and the side faces of the first drain regions 12. The first well region 15 is in contact with the lower face of the first channel region 16.

In the present embodiment, since the first channel region 16 has the same conductivity type as the first source region 11, no pn junction is formed between the first source region 11 and the first channel region 16. The first channel region 16 of the present embodiment functions as a portion of the first source region 11.

The second well region 17 and the second channel region 18 are a p-type region and an n-type region in the substrate 1, respectively. The second well region 17 and the second channel region 18 are formed below the p-type transistors Trₚ₁ to Trₚ₄. The second channel region 18 is in contact with the lower faces of the gate insulators 3, the lower face and the side faces of the second source region 13, and the lower faces and the side faces of the second drain regions 14. The second well region 17 is in contact with the lower face of the second channel region 18.

In the present embodiment, since the second channel region 18 has the same conductivity type as the second source region 13, no pn junction is formed between the second source region 13 and the second channel region 18. The second channel region 18 of the present embodiment functions as a portion of the second source region 13.

Signs D₁ and D₂ designate a first distance and a second distance between the gate conductors 4 adjacent to each other, respectively.

The first distance D₁ designates a distance between a gate conductor 4 that includes the n-type transistor Trₙ₁ and the p-type transistor Trₚ₁ and a gate conductor 4 that includes the n-type transistor Trₙ₂ and the p-type transistor Trₚ₂. Accordingly, the first distance D₁ designates a distance between the gate conductors 4 that sandwich the first source region 11 and the second source region 13. The first distance D₁ is an example of a first distance between the pair of first portions.

The second distance D₂ designates a distance between a gate conductor 4 that includes the n-type transistor Trₙ₁ and the p-type transistor Trₚ₁ and a gate conductor 4 that includes the n-type transistor Trₙ₃ or the p-type transistor Trₚ₃. Furthermore, the second distance D₂ designates a distance between a gate conductor 4 that includes the n-type transistor Trₙ₂ and the p-type transistor Trₚ₂ and a gate conductor 4 that includes the n-type transistor Trₙ₄ or the p-type transistor Trₚ₄. Accordingly, the second distance D₂ designates a distance between the gate conductors 4 that sandwich the first drain regions 12 and the second drain regions 14. The second distance D₂ is an example of a second distance between the pair of second portions.

In the present embodiment, the first distance D₁ is set shorter than the second distance D₂ (D₁<D₂). More specifically, a difference between the first distance D₁ and the second distance D₂ is set to be 20 nm or more (D₂−D₁≧20 nm). Reasons for applying such a setting are mentioned later.

[Method of Manufacturing Semiconductor Device of First Embodiment]

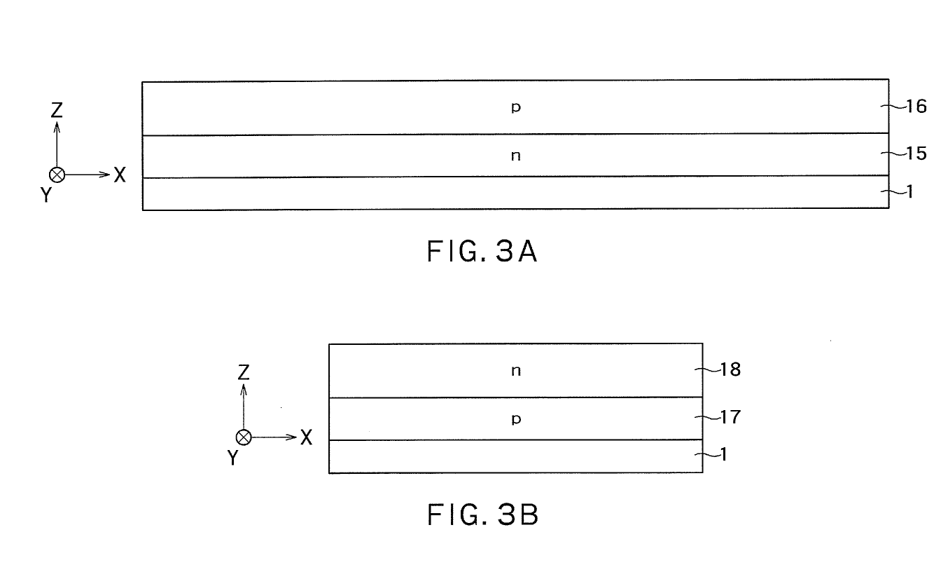

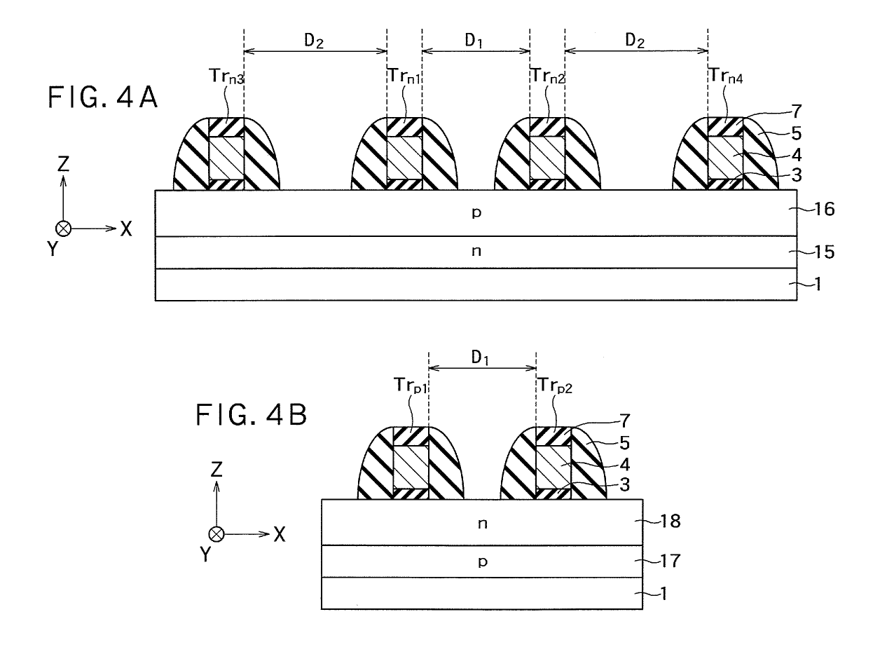

FIGS. 3A to 11B are cross-sectional views illustrating a method of manufacturing the semiconductor device of the first embodiment. FIG. 3A illustrates a cross-section taken along the I-I′ line illustrated in FIG. 1. FIG. 3B illustrates a cross-section taken along the J-J′ line illustrated in FIG. 1. The same holds true for FIG. 4A to FIG. 11B.

First, the isolation regions 2 (not shown) are formed on the surface of the substrate 1 in FIGS. 3A and 3B. An example of the thickness of the isolation regions 2 is 200 to 300 nm. For example, the isolation regions 2 can be formed by forming isolation trenches on the surface of the substrate 1 by lithography and etching, embedding a silicon oxide film in the isolation trenches, and planarizing the surface of the silicon oxide film by chemical mechanical polishing (CMP).

Next, a silicon oxide film (not shown) is formed on the surfaces of device regions of the substrate 1 in FIGS. 3A and 3B. An example of the thickness of the silicon oxide film is 10 nm or less.

As illustrated in FIGS. 3A and 3B, ion implantation and activation rapid thermal annealing (RTA) are performed for forming the first well region 15, the first channel region 16, the second well region 17 and the second channel region 18 in the substrate 1.

An example of n-type impurities for the first well region 15 is phosphorus (P). In the ion implantation for the first well region 15, the ion implantation energy is set to be 500 keV and the dosage of the n-type impurity is set to be 3.0×10¹³ cm⁻².

An example of p-type impurities for the first channel region 16 is boron (B). In the ion implantation for the first channel region 16, the ion implantation energy is set to be 10 keV and the dosage of the p-type impurity is set to be 1.0×10¹⁴ cm⁻².

An example of p-type impurities for the second well region 17 is boron. In the ion implantation for the second well region 17, the ion implantation energy is set to be 260 keV and the dosage of the p-type impurity is set to be 2.0×10¹³ cm⁻².

An example of n-type impurities for the second channel region 18 is phosphorus. In the ion implantation for the second channel region 18, the ion implantation energy is set to be 10 keV and the dosage of the n-type impurity is set to be 1.0×10¹⁴ cm⁻².

As illustrated in FIGS. 4A and 4B, the gate conductors 4 and the first mask layers 7 are formed on the first and second channel regions 16 and 18 via the gate insulators 3. The sidewall insulators 5 are then formed on the side faces of the gate conductors 4 and the first mask layers 7. In this way, gate structures for the n-type transistors Trₙ₁ to Trₙ₈ and the p-type transistors Trₚ₁ to Trₚ₄ are formed on the substrate 1.

For example, the gate insulators 3, the gate conductors 4 and the first mask layers 7 can be formed by the following procedures. First, a silicon oxide film for the gate insulators 3 is formed on the surface of the substrate 1 by thermal oxidation or low pressure chemical vapor deposition (LPCVD). An example of the thickness of the silicon oxide film is 0.5 to 6.0 nm. A polysilicon layer for the gate conductors 4 is formed on the silicon oxide film. An example of the thickness of the polysilicon layer is 50 to 200 nm. A silicon nitride film for the first mask layers 7 is formed on the polysilicon layer. Next, the gate insulators 3, the gate conductors 4 and the first mask layers 7 are respectively formed of the silicon oxide film, the polysilicon layer and the silicon nitride film by lithography and etching. Examples of this lithography are optical lithography, X-ray lithography, electron beam lithography and the like. Examples of this etching are reactive ion etching (RIE) and the like.

For example, the sidewall insulators 5 can be formed by the following procedures. First, a silicon nitride film is formed on the whole surface of the substrate 1 by LPCVD. An example of the thickness of the silicon nitride film is 20 to 80 nm. The silicon nitride film is then processed into the sidewall insulators 5 by RIE.

In the present embodiment, predoping may be performed to implant n-type impurities in the gate electrodes of the n-type transistors Trₙ₁ to Trₙ₈ and to implant p-type impurities in the gate electrodes of the p-type transistors Trₚ₁ to Trₚ₄. Examples of the n-type and the p-type impurities for the predoping are phosphorus and boron, respectively. For example, in the predoping of the n-type impurities, the ion implantation energy is set to be 5 keV and the dosage of the n-type impurities is set to be 5.0×10¹⁵ cm⁻². For example, in the predoping of the p-type impurities, the ion implantation energy is set to be 2.5 keV and the dosage of the p-type impurities is set to be 5.0×10¹⁵ cm⁻².

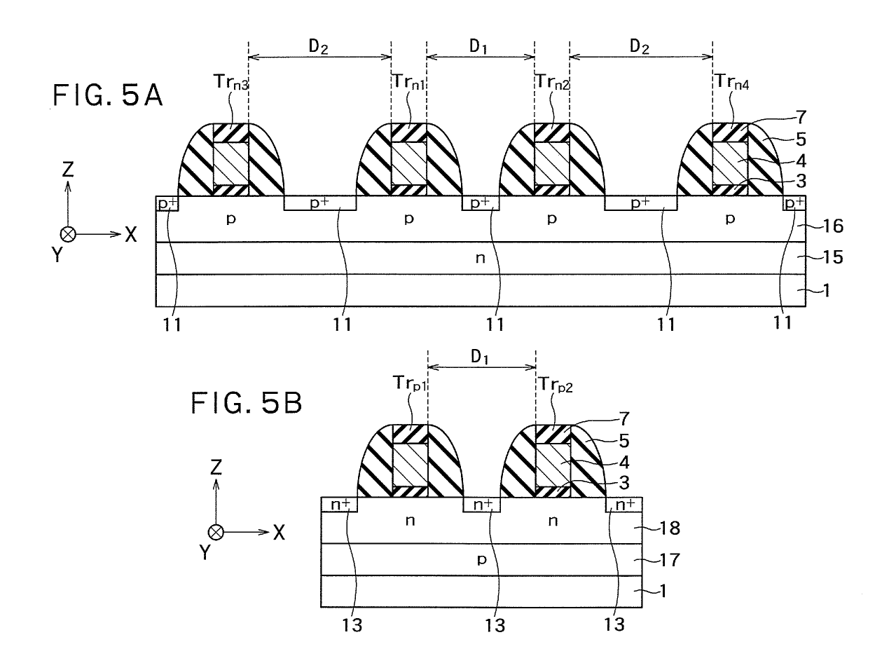

Next, a resist mask (not shown) which has openings only in the regions of the n-type transistors Trₙ₁ to Trₙ₈ is formed on the substrate 1. As illustrated in FIG. 5A, p⁺-type impurity regions 11 are formed in the substrate 1 by ion implantation using the resist mask. As a result, the impurity regions 11 are formed in regions between the gate electrodes of the n-type transistors Trₙ₁ to Trₙ₈ and the like. These regions are examples of the first region between the pair of first portions and the second region between the pair of second portions. Moreover, the p-type impurities in the impurity regions 11 are an example of first impurities. The impurity regions 11 partly become the first source regions 11 after annealing which is mentioned later.

An example of the p-type impurities for the impurity regions 11 is boron. In the ion implantation for the impurity regions 11, the ion implantation energy is set to be 2 keV and the dosage of the p-type impurity is set to be 2.0×10¹⁵ to 4.0×10¹⁵ cm⁻².

Next, a resist mask (not shown) which has openings only in the regions of the p-type transistors Trₚ₁ to Trₚ₄ is formed on the substrate 1. As illustrated in FIG. 5B, n⁺-type impurity regions 13 are formed in the substrate 1 by ion implantation using the resist mask. As a result, the impurity regions 13 are formed in regions between the gate electrodes of the p-type transistors Trₚ₁, Trₚ₂ and the like. These regions are examples of the first region between the pair of first portions and the second region between the pair of second portions. Moreover, the n-type impurities in the impurity regions 13 are an example of the first impurities. The impurity regions 13 partly become the second source regions 13 after the annealing which is mentioned later.

An example of the n-type impurities for the impurity regions 13 is arsenic (As). In the ion implantation for the impurity regions 13, the ion implantation energy is set to be 10 keV and the dosage of the n-type impurity is set to be 2.0×10¹⁵ to 4.0×10¹⁵ cm⁻².

In the present embodiment, the annealing is not performed immediately after forming the impurity regions 11 and 13. The reason is that etching is readily performed when portions of the impurity regions 11 and 13 are etched as mentioned later.

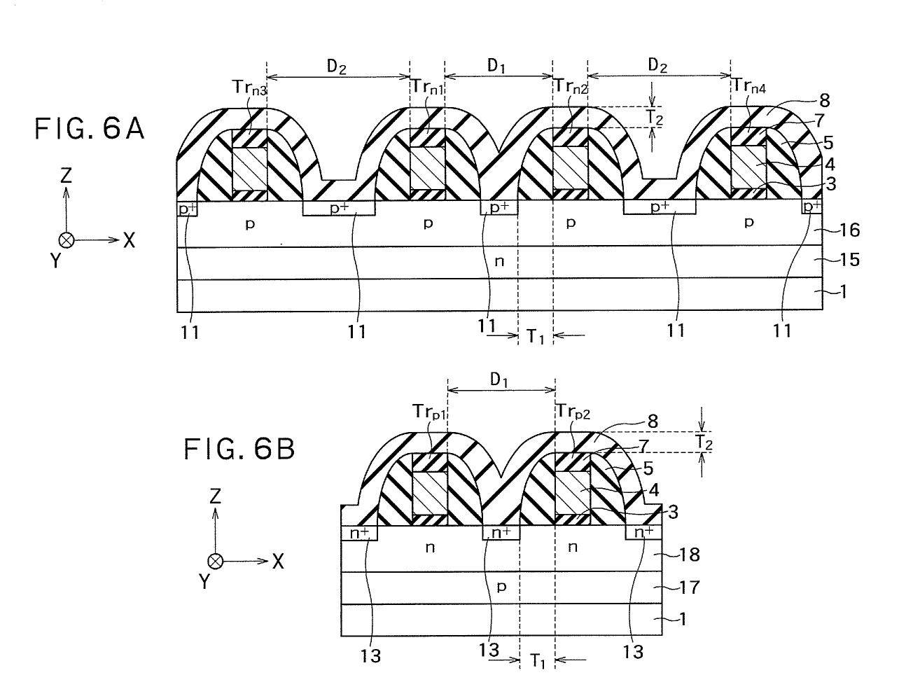

As illustrated in FIGS. 6A and 6B, a second mask layer 8 is formed on the whole surface of the substrate 1. As a result, the n-type transistors Trₙ₁ to Trₙ₈, the p-type transistors Trₚ₁ to Trₚ₄ and the impurity regions 11 and 13 are covered with the second mask layer 8. An example of the second mask layer 8 is an insulator layer such as a TEOS film.

Sign T₁ designates a thickness of each sidewall insulator 5. Sign T₂ designates a thickness of the second mask layer 8. The thickness T₂ of the second mask layer 8 of the present embodiment is set so as to satisfy the conditions “D₁−2D₁<2T₂” and “D₂−2T₁>2T₂”. As a result, the regions of the first distance D₁ are closed with the second mask layer 8. The height of the upper face of the second mask layer 8 near the centers of the regions of the first distance D₁ is higher than the height of the upper face of the second mask layer 8 near the centers of the regions of the second distance D₂. In the present embodiment, in order to realize such closure, the first distance D₁ is set to be shorter than the second distance D₂. An example of the thickness T₂ of the second mask layer 8 is 60 nm.

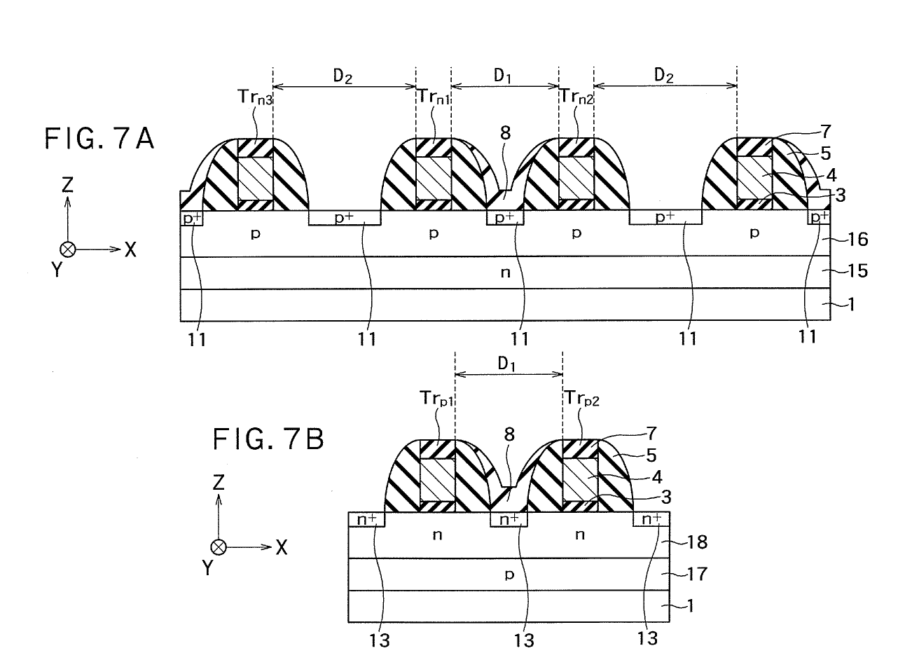

As illustrated in FIGS. 7A and 7B, the second mask layer 8 is etched back by RIE. In the present embodiment, the regions of the first distance D₁ are closed with the second mask layer 8. Therefore, the second mask layer 8 can be removed from the regions of the second distance D₂ while the second mask layer 8 is allowed to remain in the regions of the first distance D₁. In other words, the second mask layer 8 that covers only the regions of the first distance D₁ can be formed by not performing lithography. The regions of the first distance D₁ are an example of the first region between the pair of first portions. The regions of the second distance D₂ are an example of the second region between the pair of second portions.

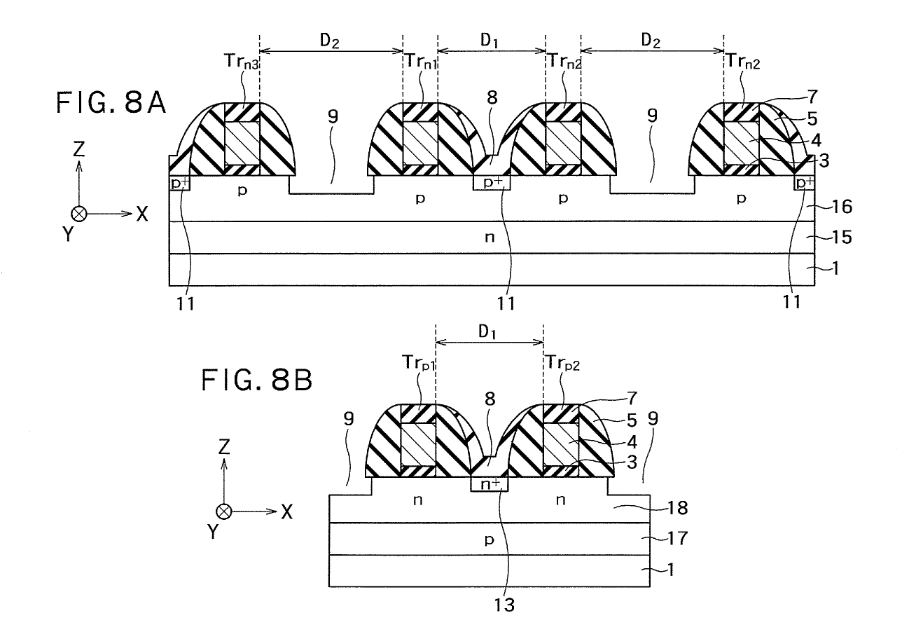

As illustrated in FIGS. 8A and 8B, the substrate 1 in the regions of the second distance D₂ is etched using the second mask layer 8 as a mask. As a result, recesses 9 are formed in the substrate 1 in the regions of the second distance D₂, and the impurity regions 11 and 13 in the regions of the second distance D₂ are removed. An example of the depth of the recesses 9 is 40 nm.

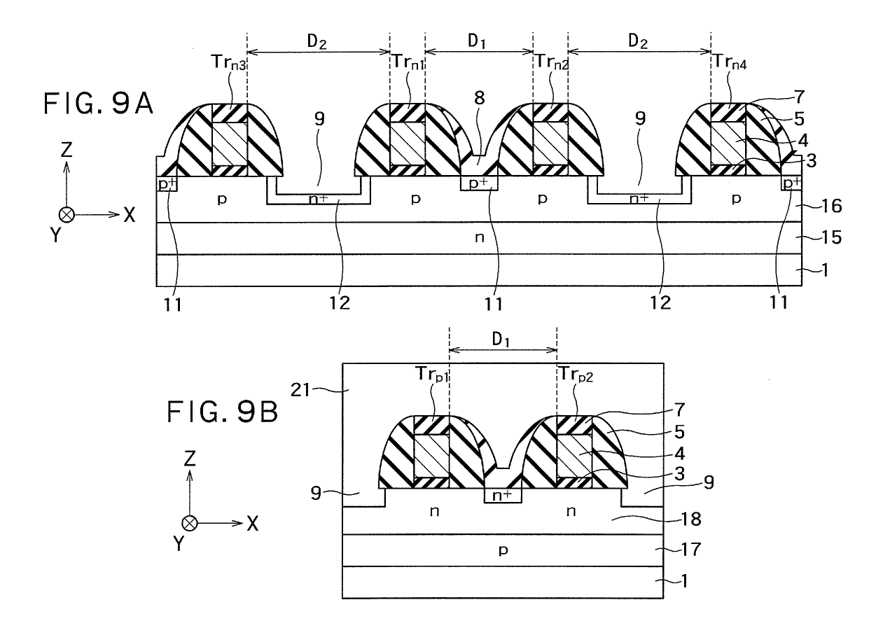

As illustrated in FIGS. 9A and 9B, a resist mask 21 which has openings only in the regions of the n-type transistors Trₙ₁ to Trₙ₈ is formed. Next, n⁺-type impurity regions 12 are formed in the substrate 1 by ion implantation using the second mask layer 8 and the resist mask 21. As a result, the impurity regions 12 are formed in regions between the gate electrodes of the n-type transistors Trₙ₁ and Trₙ₂ and the gate electrodes of the n-type transistors Trₙ₃ and Trₙ₄ and the like. These regions are examples of the second region between the pair of second portions. Moreover, the n-type impurities in the impurity regions 12 are an example of the second impurities. The impurity regions 12 become the first drain regions 12 after the annealing which is mentioned later.

An example of the n-type impurities for the impurity region 12 is arsenic. In the ion implantation for the impurity regions 12, the ion implantation energy is set to be 5 keV and the dosage of the n-type impurity is set to be 2.0×10¹⁵ to 4.0×10¹⁵ cm⁻². As to the ion implantation for the impurity regions 12, the n-type impurity is desirable to be implanted shallowly such that the impurity ions do not penetrate the second mask layer 8. Otherwise, the resist mask 21 may be formed also on the second mask layer 8 such that the impurity ions do not penetrate the second mask layer 8. In this case, the boundary of the resist mask 21 is not necessary to be formed on the gate conductors 4. Therefore, high-precision lithography for patterning of the resist mask 21 is not necessary.

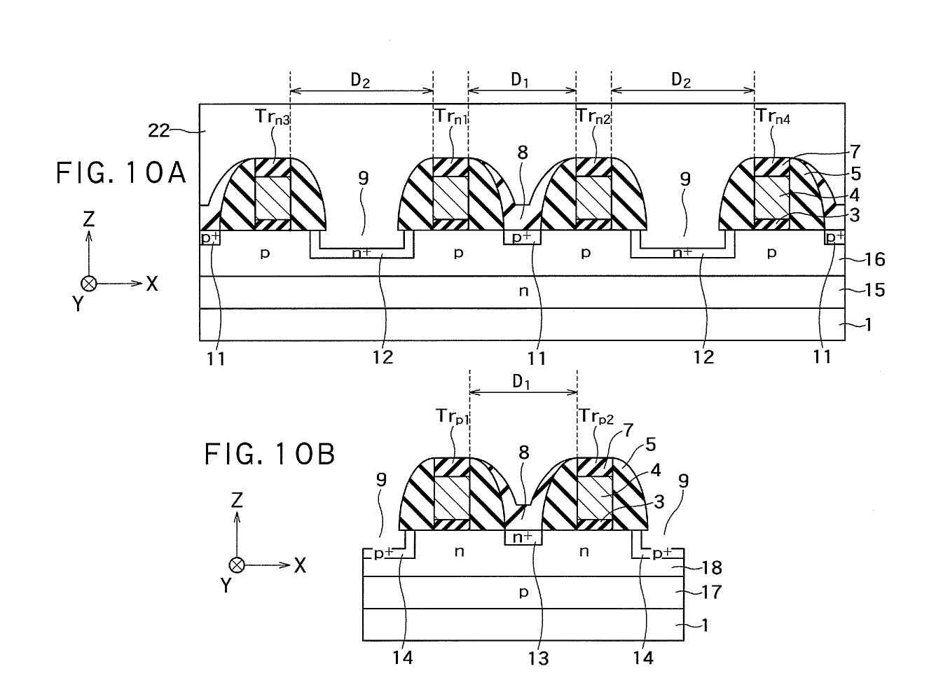

As illustrated in FIGS. 10A and 10B, a resist mask 22 which has openings only in the regions of the p-type transistors Trₚ₁ to Trₚ₄ is formed. Next, p⁺-type impurity regions 14 are formed in the substrate 1 by ion implantation using the second mask layer 8 and the resist mask 22. As a result, the impurity regions 14 are formed in regions adjacent to the gate electrodes of the p-type transistors Trₚ₁ and Trₚ₂ and the like. These regions are examples of the second region between the pair of second portions. Moreover, the p-type impurities in the impurity regions 14 are an example of the second impurities. The impurity regions 14 become the second drain regions 14 after the annealing which is mentioned later.

An example of the p-type impurities for the impurity region 14 is boron. In the ion implantation for the impurity regions 14, the ion implantation energy is set to be 1.5 keV and the dosage of the p-type impurity is set to be 2.0×10¹⁵ to 4.0×10¹⁵ cm⁻². As to the ion implantation for the impurity regions 14, the p-type impurity is desirable to be implanted shallowly such that the impurity ions do not penetrate the second mask layer 8. Otherwise, the resist mask 22 may be formed also on the second mask layer 8 such that the impurity ions do not penetrate the second mask layer 8. In this case, the boundary of the resist mask 22 is not necessary to be formed on the gate conductors 4. Therefore, high-precision lithography for patterning of the resist mask 22 is not necessary.

Semiconductor layers such as silicon layers may be formed in the recesses 9 between the process of FIGS. 8A and 8B and the processes of FIGS. 9A and 9B and FIGS. 10A and 10B. In this case, the impurity regions 12 and 14 are formed in the semiconductor layers in the recesses 9. For example, the semiconductor layers can be formed by selective epitaxial growth.

The process of FIGS. 8A and 8B may be omitted. In this case, the dosage of the n-type impurities in the impurity regions 12 is set such that the effect of the p-type impurities in the impurity regions 11 is compensated since the impurity regions 12 are formed to be superimposed on the impurity regions 11 in the process of FIGS. 9A and 9B. Moreover, the dosage of the p-type impurities in the impurity regions 14 is set such that the effect of the n-type impurity in the impurity regions 13 is compensated since the impurity regions 14 are formed to be superimposed on the impurity regions 13 in the process of FIGS. 10A and 10B.

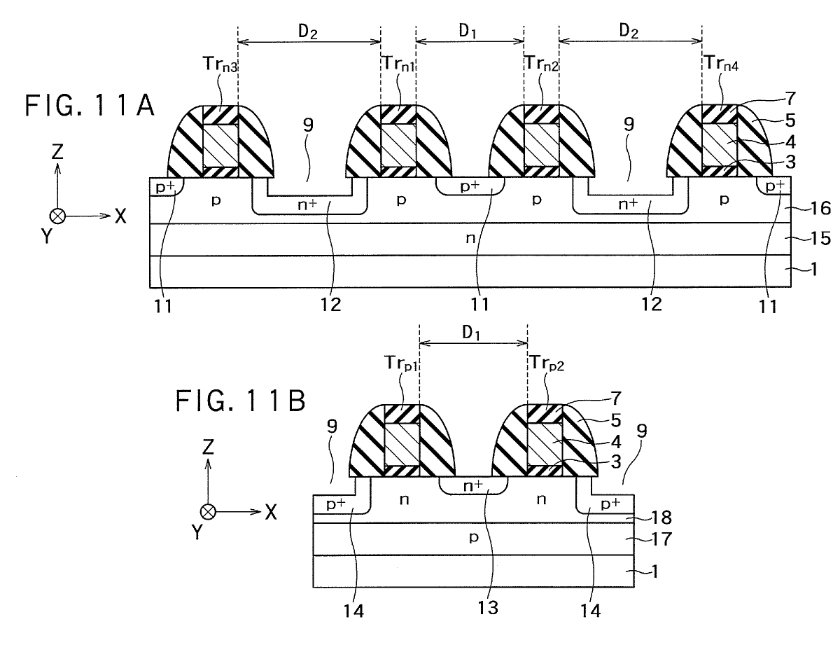

The activation annealing of the substrate 1 is then performed. As a result, the first source regions 11, the first drain regions 12, the second source regions 13 and the second drain regions 14 are formed from the impurity regions 11 to 14 (FIGS. 11A and 11B). The activation annealing of the substrate 1 is performed, for example, at 1030° C. by spike annealing. As illustrated in FIGS. 11A and 11B, the second mask layer 8 on the substrate 1 is then removed entirely.

Thereafter, a protective film for protecting the sidewall insulators 5 is formed on the substrate 1, and the first mask layers 7 are exposed from the protective film. The exposed first mask layers 7 are removed with hot phosphoric acid to expose the gate conductors 4 from the first mask layers 7. Silicide layers (for example, nickel silicide layers) are formed in the exposed gate conductors 4. Next, inter layer dielectrics, contact plugs, via plugs, interconnect layers, passivation films and the like are formed on the substrate 1 to form interconnects for connecting the n-type transistors Trₙ₁ to Trₙ₈ and the p-type transistors Trₚ₁ to Trₚ₄. In this way, the semiconductor device of the present embodiment is manufactured.

As described above, in the present embodiment, the first distance D₁ between the gate conductors 4 sandwiching the first source regions 11 and the second source regions 13 is set shorter than the second distance D₂ between the gate conductors 4 sandwiching the first drain regions 12 and the second drain regions (D₁<D₂). Therefore, the present embodiment makes it possible to form the second mask layer 8 that covers the regions of the first distances D₁ and that is removed from the regions of the second distance D₂ by not using lithography.

Therefore, when a TFET is fabricated to include the gate electrode (gate conductor 4) whose gate length is short and the source region 11 or 13 and the drain region 12 or 14 which have different conductivity types, the present embodiment makes it possible to form the source region 11 or 13 and the drain region 12 or 14 by not using high-precision lithography. Therefore, the present embodiment makes it possible to reduce the circuit area in the case of using the TFET including the source region 11 or 13 and the drain region 12 or 14 which have different conductivity types. In other words, the present embodiment makes it possible to attenuate the restriction of the gate length in the case of using the TFET.

In the present embodiment, the first distance D₁ is desirable to be sufficiently shorter than the second distance D₂. Namely, the difference between the first distance D₁ and the second distance D₂ is desirable to be set sufficiently large. The reason is that, if the difference is small, there is a concern that the second mask layer 8 that covers the regions of the first distance D₁ is thin and the second mask layer 8 cannot sufficiently function as a mask in the processes of FIGS. 9A and 9B and FIGS. 10A and 10B. Therefore, in the present embodiment, the difference between the first distance D₁ and the second distance D₂ is set to be 20 nm or more (D₂−D₁≧20 nm).

In the present embodiment, the distance between the gate conductors 4 sandwiching the first drain region 12 and the second drain region 14 may be set to be the first distance D₁, and the distance between the gate conductors 4 sandwiching the first source regions 11 and the second source regions 13 may be set to be the second distance D₂. In this case, the impurity regions 12 and 14 are formed in the process of FIGS. 5A and 5B, and the impurity regions 11 and 13 are formed in the processes of FIGS. 9A and 9B and FIGS. 10A and 10B. The same holds true for modifications of the first embodiment and for second and third embodiments mentioned later.

### Modifications of First Embodiment

The first embodiment can also be applied to a NOR circuit and a NAND circuit. Modifications of the first embodiment will be described.

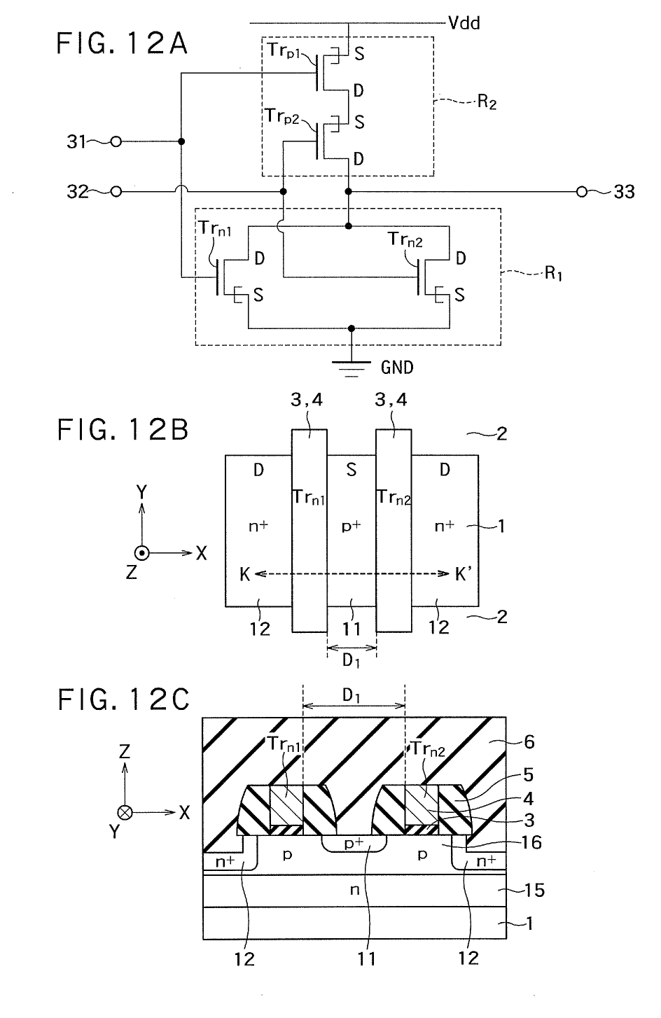

FIGS. 12A to 12C are a circuit diagram, a plan view and a cross-sectional view illustrating a structure of a semiconductor device of a first modification of the first embodiment. The semiconductor device of the present modification includes a NOR circuit.

As illustrated in FIG. 12A, the semiconductor device of the present modification includes n-type transistors Trₙ₁ and Trₙ₂, p-type transistors Trₚ₁ and Trₚ₂, a first input portion 31, a second input portion 32 and an output portion 33 forming the NOR circuit.

All of the n-type transistors Trₙ₁ and Trₙ₂ and the p-type transistors Trₚ₁ and Trₚ₂ are TFETs.

The n-type transistors Trₙ₁ and Trₙ₂ are connected to each other in parallel. The gates G of the n-type transistors Trₙ₁ and Trₙ₂ are electrically connected to first and second input portions 31 and 32, respectively. The sources S of the n-type transistors Trₙ₁ and Trₙ₂ are electrically connected to the ground voltage (GND). The drains D of the n-type transistors Trₙ₁ and Trₙ₂ are electrically connected to the drain D of the p-type transistor Trₚ₂ and the output portion 33.

The p-type transistors Trₚ₁ and Trₚ₂ are connected to each other in series. The gates G of the p-type transistors Trₚ₁ and Trₚ₂ are electrically connected to first and second input portions 31 and 32, respectively. The source S of the p-type transistor Trₚ₁ is electrically connected to the power supply voltage (Vdd). The drain D of the p-type transistor Trₚ₁ is electrically connected to the source S of the p-type transistor Trₚ₂. The drain D of the p-type transistor Trₚ₂ is electrically connected to the output portion 33.

FIG. 12B is a plan view illustrating a region R₁ in FIG. 12A, and illustrates the n-type transistors Trₙ₁ and Trₙ₂ connected to each other in parallel. The gate conductors 4 illustrated in FIG. 12B are the gate electrodes of these transistors.

FIG. 12C is a cross-sectional view taken along the K-K′ line illustrated in FIG. 12B. As illustrated here, the n-type transistors Trₙ₁ and Trₙ₂ of the present modification have similar structures to those of the n-type transistors Trₙ₁ and Trₙ₂ of the first embodiment (refer to FIG. 2A). In the present modification, the first distance D₁ between the gate conductors 4 sandwiching the first source region 11 is set shorter than the second distance D₂ (not shown) between the gate conductors 4 sandwiching the first drain regions 12. Thereby, the present modification can realize a similar effect to that of the first embodiment.

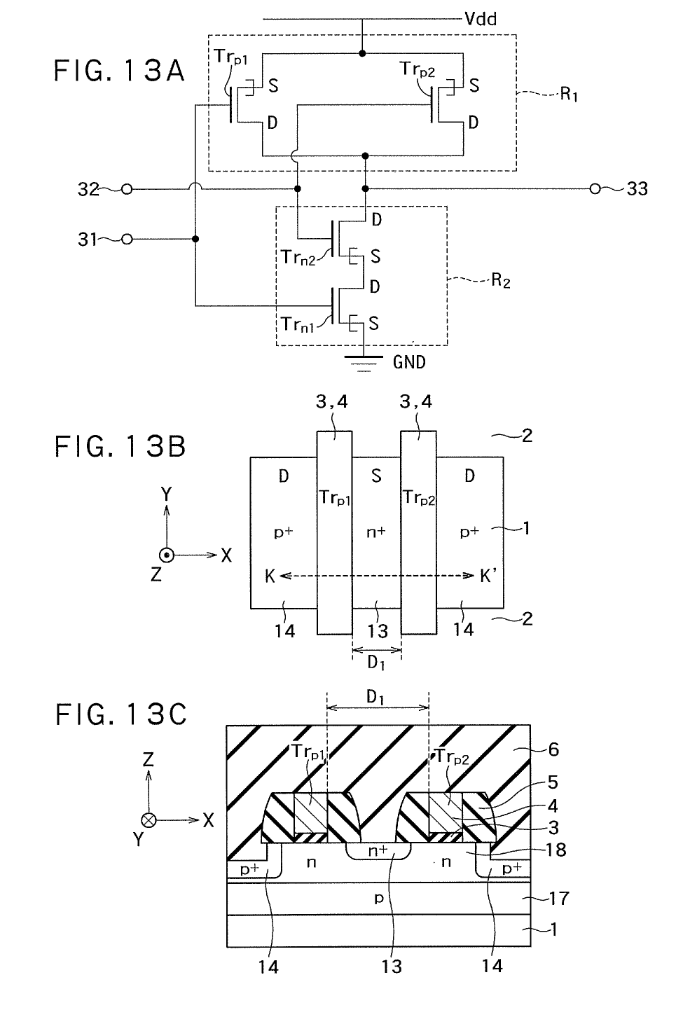

FIGS. 13A to 13C are a circuit diagram, a plan view and a cross-sectional view illustrating a structure of a semiconductor device of a second modification of the first embodiment. The semiconductor device of the present modification includes a NAND circuit.

As illustrated in FIG. 13A, the semiconductor device of the present modification includes the n-type transistors Trₙ₁ and Trₙ₂, the p-type transistors Trₚ₁ and Trₚ₂, the first input portion 31, the second input portion 32 and the output portion 33 forming the NAND circuit. All of the n-type transistors Trₙ₁ and Trₙ₂ and the p-type transistors Trₚ₁ and Trₚ₂ are TFETs.

The n-type transistors Trₙ₁ and Trₙ₂ are connected to each other in series. The gates G of the n-type transistors Trₙ₁ and Trₙ₂ are electrically connected to the first and second input portions 31 and 32, respectively. The source S of the n-type transistor Trₙ₁ is electrically connected to the ground voltage (GND). The drain D of the n-type transistor Trₙ₁ is electrically connected to the source S of the n-type transistor Trₙ₂. The drain D of the n-type transistor Trₙ₂ is electrically connected to the drains D of the p-type transistors Trₚ₁ and Trₚ₂ and the output portion 33.

The p-type transistors Trₚ₁ and Trₚ₂ are connected to each other in parallel. The gates G of the p-type transistors Trₚ₁ and Trₚ₂ are electrically connected to the first and second input portions 31 and 32, respectively. The sources S of the p-type transistors Trₚ₁ and Trₚ₂ are electrically connected to the power supply voltage (Vdd). The drains D of the p-type transistors Trₚ₁ and Trₚ₂ are electrically connected to the output portion 33.

FIG. 13B is a plan view illustrating the region R₁ in FIG. 13A, and illustrates the p-type transistors Trₚ₁ and Trₚ₂ connected to each other in parallel. The gate conductors 4 illustrated in FIG. 13B are the gate electrodes of these transistors.

FIG. 13C is a cross-sectional view taken along the K-K′ line illustrated in FIG. 13B. As illustrated here, the p-type transistors Trₚ₁ and Trₚ₂ of the present modification have similar structures to those of the p-type transistors Trₚ₁ and Trₚ₂ of the first embodiment (refer to FIG. 2B). In the present modification, the first distance D₁ between the gate conductors 4 sandwiching the second source region 13 is set shorter than the second distance D₂ (not shown) between the gate conductors 4 sandwiching the second drain region 14. Thereby, the present modification can realize a similar effect to that of the first embodiment.

### Second Embodiment

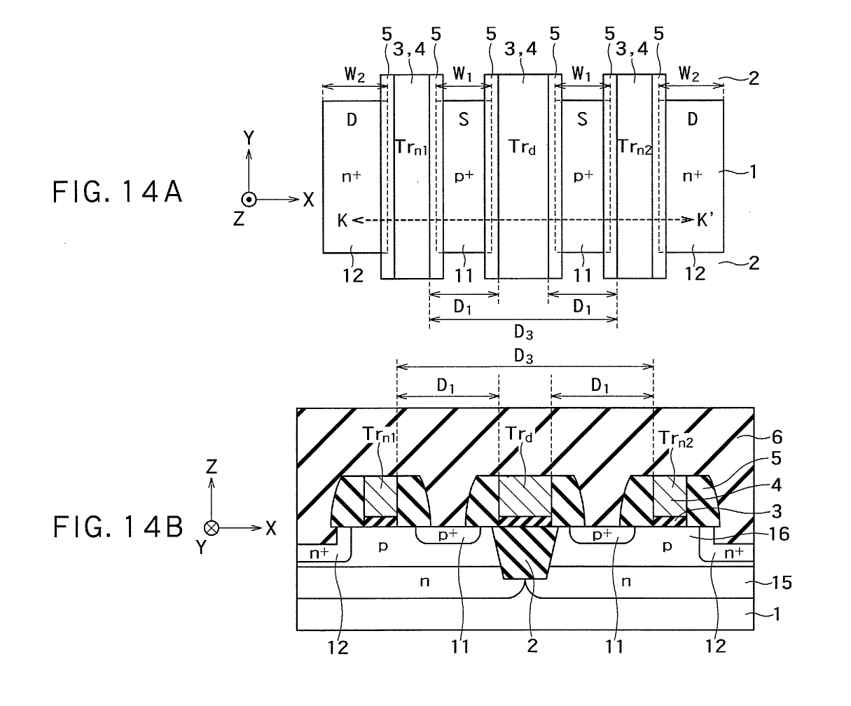

FIGS. 14A and 14B are a plan view and a cross-sectional view illustrating a structure of a semiconductor device of a second embodiment.

The semiconductor device of the present embodiment includes a NAND circuit similarly to the semiconductor device of the second modification of the first embodiment (FIGS. 13A to 13C). The NAND circuit of the present embodiment has a circuit configuration illustrated in FIG. 13A.

FIG. 14A is a plan view illustrating a region R₂ in FIG. 13A. FIG. 14A illustrates the n-type transistors Trₙ₁ and Trₙ₂ connected to each other in series, and a dummy transistor Tr_{d} sandwiched between the n-type transistors Trₙ₁ and Trₙ₂. Each of the n-type transistors Trₙ₁ and Trₙ₂ is formed between the first source region 11 and the first drain region 12 and functions as a TFET. Meanwhile, the dummy transistor Tr_{d} is formed between the first source regions 11 and does not function as a TFET.

FIG. 14A illustrates the gate electrode (gate conductor 4) of the n-type transistor Trₙ₁, the gate electrode (gate conductor 4) of the n-type transistor Trₙ₂, and a dummy gate electrode (gate conductor 4) of the dummy transistor Tr_{d}. The dummy gate electrode is adjacent to these gate electrodes.

These gate electrodes are examples of one of the pair of first portions, and the dummy gate electrode is an example of the other of the pair of first portions. The first source regions 11 and the first drain regions 12 are examples of the first and second diffusion regions, respectively. The n-type transistors Trₙ₁ and Trₙ₂ are examples of the first transistor.

The gate conductor 4 including the dummy gate electrode may include a gate electrode with the dummy gate electrode, or may include no gate electrode. In the former case, the dummy gate electrode functions, for example, as a gate interconnect for supplying the gate voltage to the gate electrode of the transistor (not shown) provided outside the region R₂ in FIG. 13A. In the latter case, the dummy gate electrode is a dummy interconnect which does not function as a gate electrode or a gate interconnect.

FIG. 14B is a cross-sectional view taken along the K-K′ line illustrated in FIG. 14A. The n-type transistors Trₙ₁ and Trₙ₂ include the gate electrodes on the first channel region 16 and function as TFETs. Meanwhile, the dummy transistor Tr_{d} includes the dummy gate electrode on the isolation region 2 and does not function as a TFET. In FIG. 14B, a width of the dummy gate electrode in the X-direction is desirable to be set narrower than the width of the isolation region 2 in the X-direction in order to suppress undesired leak current from arising.

Here, a function of the dummy transistor Tr_{d} of the present embodiment will be described.

The first distance D₁ of the present embodiment designates the distance between the gate conductors 4 sandwiching the first source regions 11 similarly to the first embodiment. The second distance D₂ (not shown) of the present embodiment designates the distance between the gate conductors 4 sandwiching the first drain regions 12 similarly to the first embodiment. Any of the first and second distances D₁ and D₂ of the present embodiment designates the distance between the gate conductors 4 in the X-direction.

Sign W₁ designates the width of the first source regions 11 in the X-direction. Sign W₂ designates the width of the first drain regions 12 in the X-direction. Hereafter, the widths W₁ and W₂ are referred to as first and second widths, respectively.

The first source regions 11 of the present embodiment are formed between a gate conductor 4 including the dummy transistor

Tr_{d} and gate conductors 4 including the n-type transistors Trₙ₁ and Trₙ₂. Therefore, the first distance D₁ of the present embodiment is the distance between the gate conductor 4 including the dummy transistor Tr_{d} and the gate conductors 4 including the n-type transistors Trₙ₁ and Trₙ₂. The first distance D₁ of the present embodiment is set shorter than the second distance D₂ (D₁<D₂).

Sign D₃ designates a third distance between a gate conductor 4 including the n-type transistor Trₙ₁ and a gate conductor 4 including the n-type transistor Trₙ₂. The third distance D₃ of the present embodiment is set longer than the second distance D₂ (D₃>D₂).

Here, it is supposed that the dummy transistor Tr_{d} is not formed between the n-type transistors Trₙ₁ and Trₙ₂ when the semiconductor device of the present embodiment is manufactured. In this case, since the third distance D₃ is longer than the second distance D₂, the region of the third distance D₃ is not closed with the second mask layer 8. Therefore, it is not possible to perform the ion implantation for the first drain regions 12 while the impurity regions for the first source regions 11 are protected by the second mask layer 8, unlikely to the first embodiment.

Therefore, the dummy transistor Tr_{d} is formed between the n-type transistors Trₙ₁ and Trₙ₂ when the semiconductor device of the present embodiment is manufactured. Thereby, the region of the third distance D₃ is divided into the regions of the first distance D₁. The regions of the first distance D₁ between the pair of first portions of the gate conductors 4 are closed with the second mask layer 8. Therefore, it is possible to perform the ion implantation for the first drain regions 12 while the impurity regions for the first source regions 11 are protected by the second mask layer 8, likely to the first embodiment.

In this way, the present embodiment makes it possible to realize the closure similarly to the first embodiment by forming the dummy transistor Tr_{d} between the n-type transistors Trₙ₁ and Trₙ₂.

The first drain regions 12 of the present embodiment may not be sandwiched between the gate conductors 4. In this case, the first distance D₁ is set sufficiently short, and the second width W₂ is set sufficiently long. This makes it possible to process the mask layer 8 such that the regions of the first distance D₁ are covered with the second mask layer 8 and the regions of the second width W₂ (regions where the first drain regions 12 are to be formed) are exposed from the second mask layer 8.

Therefore, in the case where the first drain regions 12 are not sandwiched between the gate conductors 4, the first distance D₁ of the present embodiment is set shorter than the second width W₂ (D₁<W₂). Moreover, the difference between the first distance D₁ and the second width W₂ is desirable to be set to be 20 nm or more (W₂−D₁≧20 nm). The second width W₂ in this case is an example of the width of the second diffusion region.

[Method of Manufacturing Semiconductor Device of Second Embodiment]

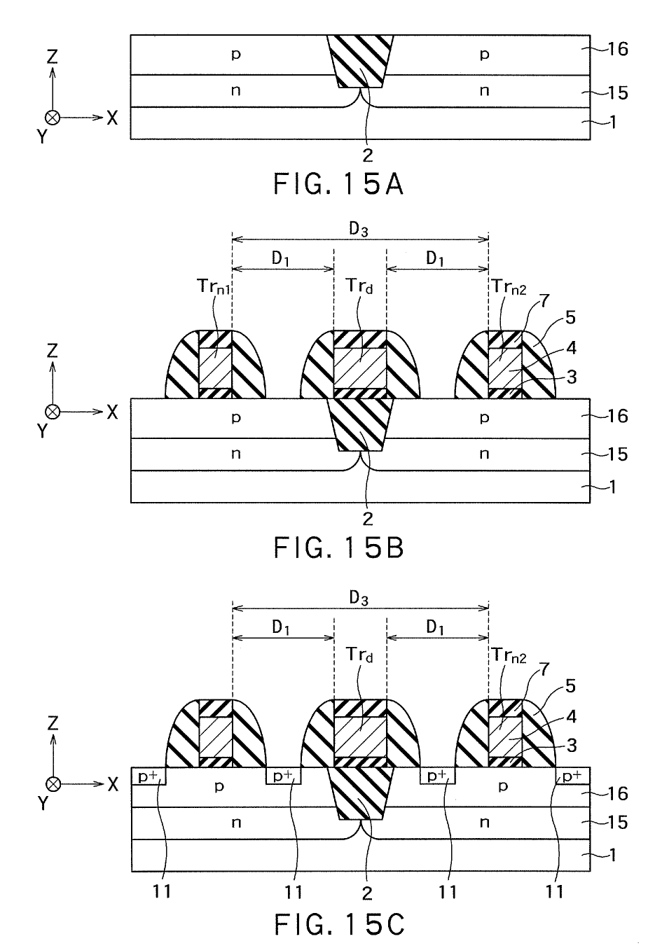

FIGS. 15A to 17C are cross-sectional views illustrating a method of manufacturing the semiconductor device of the second embodiment. FIG. 15A to FIG. 17C illustrate cross-sections taken along the K-K′ line illustrated in FIG. 14A.

First, as illustrated in FIG. 15A, the isolation region 2 is formed on the surface of the substrate 1. Next, ion implantation and activation RTA are performed for forming the first well region 15, the first channel region 16, the second well region 17 (not shown) and the second channel region 18 (not shown) in the substrate 1.

As illustrated in FIG. 15B, the gate conductors 4 and the first mask layers 7 are formed on the substrate 1 and on the isolation region 2 via the gate insulators 3. The sidewall insulators 5 are then formed on the side faces of the gate conductors 4 and the first mask layers 7. In this way, the gate structures for the n-type transistors Trₙ₁ and Trₙ₂, the p-type transistors Trₚ₁ and Trₚ₂ (not shown), and the dummy transistor Tr_{d} is formed on the substrate 1 and the isolation region 2.

Next, a resist mask (not shown) which has openings only in the regions of the n-type transistors Trₙ₁ and Trₙ₂ is formed on the substrate 1. As illustrated in FIG. 15C, the p⁺-type impurity regions 11 are formed in the substrate 1 by ion implantation using the resist mask. Using a similar method, the n⁺-type impurity regions 13 (not shown) are also formed in the substrate 1.

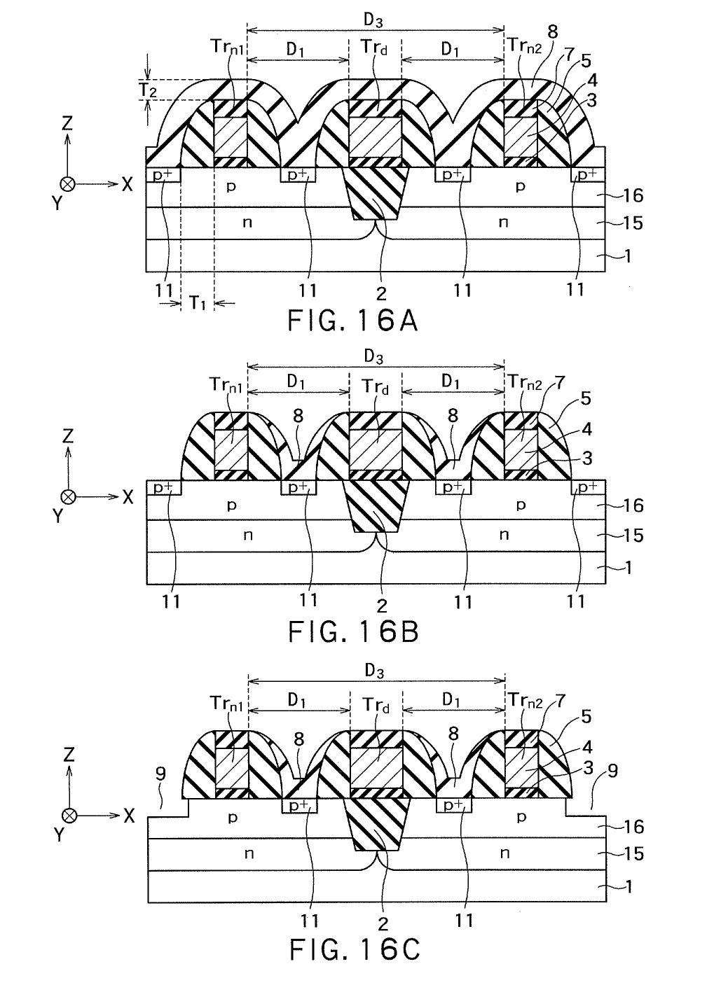

As illustrated in FIG. 16A, the second mask layer 8 is formed on the whole surface of the substrate 1. As a result, the n-type transistors Trₙ₁ and Trₙ₂, the p-type transistors Trₚ₁ and Trₚ₂, the dummy transistor Tr_{d} and the impurity regions 11 and 13 are covered with the second mask layer 8.

Sign T₁ designates a thickness of each sidewall insulator 5. Sign T₂ designates a thickness of the second mask layer 8. The thickness T₂ of the second mask layer 8 of the present embodiment is set so as to satisfy the conditions “D₁−2T₁<2T₂” and “D₂−2T₁>2T₂”. As a result, the regions of the first distance D₁ are closed with the second mask layer 8. The height of the upper face of the second mask layer 8 near the centers of the regions of the first distance D₁ is higher than the height of the upper face of the second mask layer 8 near the centers of the regions of the second distance D₂. In the present embodiment, in order to realize such closure, the first distance D₁ is set shorter than the second distance D₂.

As illustrated in FIG. 16B, the second mask layer 8 is etched back by RIE. In the present embodiment, the regions of the first distance D₁ are closed with the second mask layer 8. Therefore, the second mask layer 8 can be removed from the regions of the second distance D₂ while the second mask layer 8 is allowed to remain in the regions of the first distance D₁. In other words, the second mask layer 8 that covers only the regions of the first distance D₁ can be formed by not performing lithography.

As illustrated in FIG. 16C, the substrate 1 in the regions of the second distance D₂ is etched using the second mask layer 8 as a mask. As a result, the recesses 9 are formed in the substrate 1 in the regions of the second distance D₂, and the impurity regions 11 in the regions of the second distance D₂ are removed. Using a similar method, the impurity regions 13 (not shown) in the regions of the second distance D₂ are also removed.

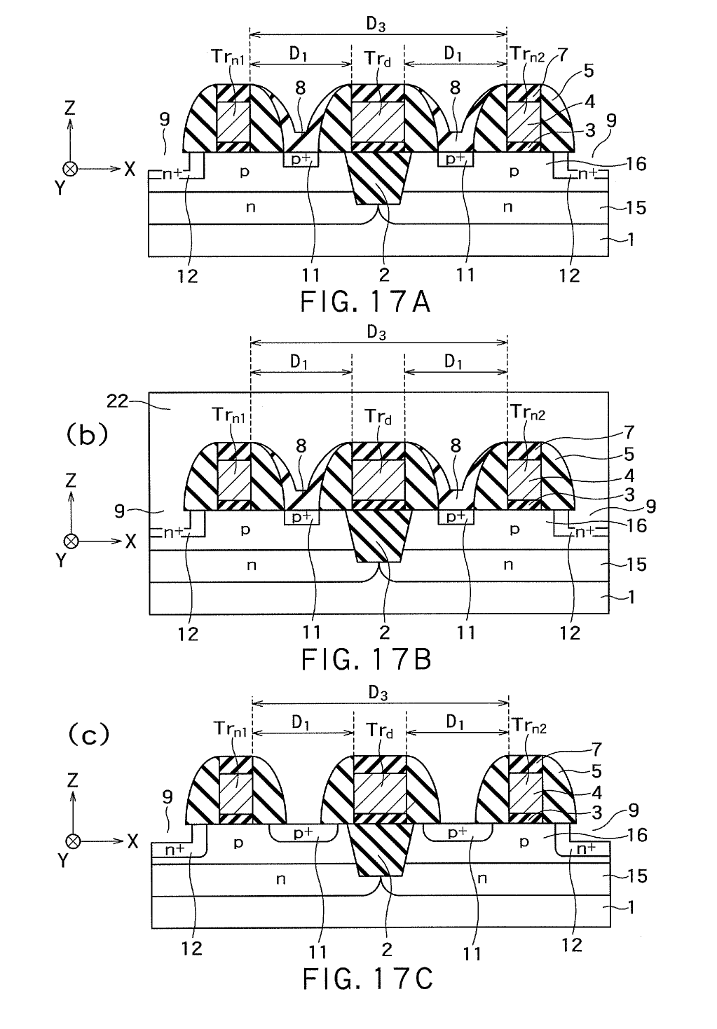

As illustrated in FIG. 17A, the resist mask 21 (not shown) which has openings only in the regions of the n-type transistors Trₙ₁ and Trₙ₂ is formed. The n⁺-type impurity regions 12 are formed in the substrate 1 by ion implantation using the second mask layer 8 and the resist mask 21.

As illustrated in FIG. 17B, the resist mask 22 which has openings only in the region of the p-type transistors Trₚ₁ and Trₚ₂ is formed. The p⁺-type impurity regions 14 (not shown) are formed in the substrate 1 by ion implantation using the second mask layer 8 and the resist mask 22.

The activation annealing of the substrate 1 is then performed. As a result, the first source regions 11 and the first drain regions 12 are formed from the impurity regions 11 and 12 (FIG. 17C). Furthermore, the second source regions 13 and second drain regions 14 (not shown) are formed from the impurity regions 13 and 14 (not shown). As illustrated in FIG. 17C, the second mask layer 8 on the substrate 1 is then removed entirely.

Thereafter, inter layer dielectrics, contact plugs, via plugs, interconnect layers, passivation films and the like are formed on the substrate 1 to form interconnects for connecting the n-type transistors Trₙ₁ and Trₙ₂ and the p-type transistors Trₚ₁ and Trₚ₂. In this way, the semiconductor device of the present embodiment is manufactured.

As described above, in the present embodiment, the gate conductors 4 including the dummy gate electrode is used such that the first distance D₁ between the gate conductors 4 sandwiching the first source regions 11 and the second source regions 13 is set shorter than the second distance D₂ between the gate conductors 4 sandwiching the first drain regions 12 and the second drain regions 14 (D₁<D₂).

Alternatively, in the present embodiment, the gate conductors 4 including the dummy gate electrode is used such that the first distance D₁ between the gate conductors 4 sandwiching the first source regions 11 and the second source regions 13 is set shorter than the second width W₂ of the first drain regions 12 and the second drain regions 14 (D₁<W₂).

Therefore, the present embodiment makes it possible to reduce the circuit area in the case of using a TFET including the source region 11 or 13 and the drain region 12 or 14 which have different conductivity types, similarly to the first embodiment. In other words, the present embodiment makes it possible to attenuate the restriction of the gate length in the case of using the TFET.

The present embodiment can be applied to the region R₂ of the NOR circuit in FIG. 12A as well as the region R₂ of the NAND circuit in FIG. 13A. Moreover, the structure of the region R₂ of the NAND circuit in the present embodiment may be used in combination with the structure of the region R₁ of the NAND circuit in the second modification of the first embodiment.

### Third Embodiment

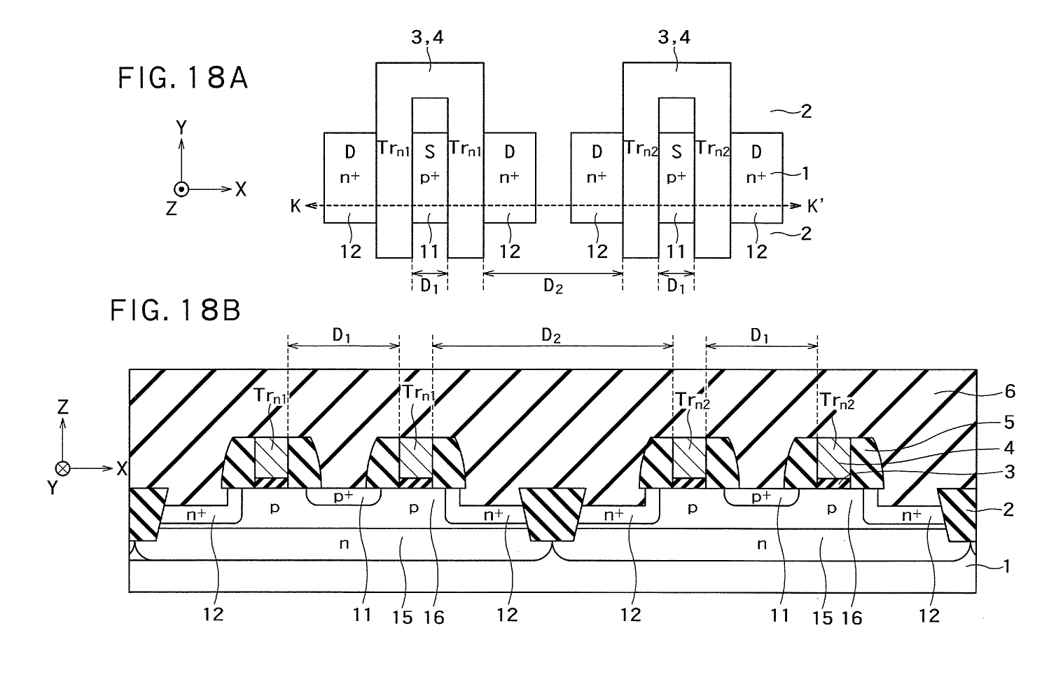

FIGS. 18A and 18B are a plan view and a cross-sectional view illustrating a structure of a semiconductor device of a third embodiment.

The semiconductor device of the present embodiment includes a NAND circuit similarly to the semiconductor device of the second modification of the first embodiment (FIGS. 13A to 13C). The NAND circuit of the present embodiment has a circuit configuration illustrated in FIG. 13A.

FIG. 18A is a plan view illustrating the region R₂ in FIG. 13A. FIG. 18A illustrates the n-type transistors Trₙ₁ and Trₙ₂ connected to each other in series.

The n-type transistor Trₙ₁ of the present embodiment has a finger structure. The n-type transistor Trₙ₁ of the present embodiment includes, as a gate electrode, two gate electrode portions included in the same gate conductor 4. The first source region 11 of the n-type transistor Trₙ₁ is sandwiched between these gate electrode portions. Moreover, each of the gate electrode portions is sandwiched between the first source region 11 and a first drain region 12. These gate electrode portions are examples of the pair of first portions.

Similarly, the n-type transistor Trₙ₂ of the present embodiment has a finger structure. The n-type transistor Trₙ₂ of the present embodiment includes, as a gate electrode, two gate electrode portions included in the same gate conductor 4. The first source region 11 of the n-type transistor Trₙ₂ is sandwiched between these gate electrode portions. Moreover, each of the gate electrode portions is sandwiched between the first source region 11 and a first drain region 12. These gate electrode portions are also examples of the pair of first portions.

Furthermore, one of the first drain regions 12 of the n-type transistor Trₙ₁ and one of the first drain regions 12 of the n-type transistor Trₙ₂ are sandwiched between one of the gate electrode portions of the n-type transistor Trₙ₁ and one of the gate electrode portions of the n-type transistor Trₙ₂. These gate electrode portions are examples of the pair of second portions.

FIG. 18B is a cross-sectional view taken along the K-K′ line illustrated in FIG. 18A. FIG. 18B illustrates the isolation regions 2 formed adjacent to the first drain regions 12 of the n-type transistor Trₙ₁ and the first drain regions 12 of the n-type transistor Trₙ₂. The isolation regions 2 in FIG. 18B is arranged between the first drain regions 12.

The first distance D₁ of the present embodiment designates the distance between the gate conductors 4 sandwiching the first source regions 11 similarly to the first and second embodiments. However, the first distance D₁ of the present embodiment is not the distance between the different gate conductors 4 but the distance between the different portions of the same gate conductor 4. Specifically, the first distance D₁ of the present embodiment designates the distance between the gate electrode portions of the n-type transistor Trₙ₁ and the distance between the gate electrode portions of the n-type transistor Trₙ₂.

The second distance D₂ of the present embodiment designates the distance between the gate conductors 4 sandwiching the first drain regions 12 similarly to the first and second embodiments. Specifically, the second distance D₂ of the present embodiment designates the distance between one of the gate electrode portions of the n-type transistor Trₙ₁ and one of the gate electrode portions of the n-type transistor Trₙ₂.

The first distance D₁ of the present embodiment is set shorter than the second distance D₂ (D₁<D₂). Thereby, the regions of the first distance D₁ are closed with the second mask layer 8 when the semiconductor device of the present embodiment is manufacturing. Therefore, it is possible to perform the ion implantation for the first drain regions 12 while the impurity regions for the first source regions 11 are protected by the second mask layer 8, likely to the first and second embodiments.

In this way, the present embodiment makes it possible to realize the closure similarly to the first and second embodiments by applying the finger structures to the n-type transistors Trₙ₁ and Trₙ₂.

In the present embodiment, the arrangement of the first source regions 11 and the arrangement of the first drain regions 12 may be exchanged. In this case, the first drain regions 12 are arranged between the two gate electrode portions of the n-type transistor Trₙ₁ and between the two gate electrode portions of the n-type transistor Trₙ₂.

In the present embodiment, the first distance D₁ between the gate conductors 4 of the finger structures sandwiching one of the first source region 11 and the first drain region 12 may be set shorter than the second width W₂ which is a width of the other of the first source region 11 and the first drain region 12 which are not sandwiched between the gate conductors 4 (D₁<W₂).

[Method of Manufacturing Semiconductor Device of Third Embodiment]

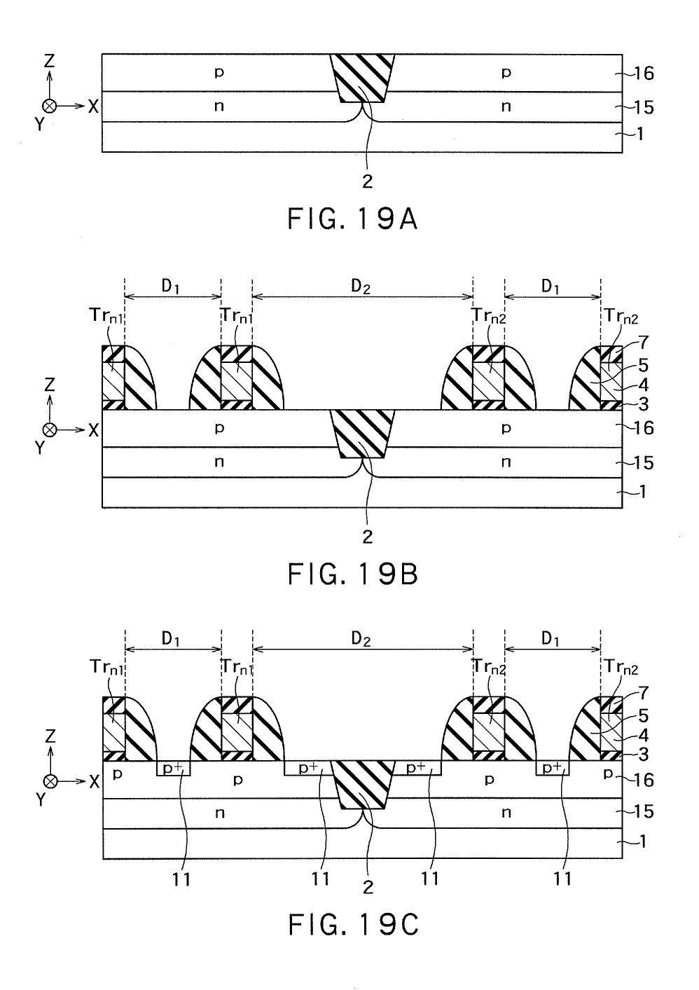

FIGS. 19A to 21C are cross-sectional views illustrating a method of manufacturing the semiconductor device of the third embodiment. FIG. 19A to FIG. 21C illustrate cross-sections taken along the K-K′ line illustrated in FIG. 18A.

First, as illustrated in FIG. 19A, the isolation region 2 is formed on the surface of the substrate 1. Next, ion implantation and activation RTA are performed for forming the first well region 15, the first channel region 16, the second well region 17 (not shown) and the second channel region 18 (not shown) in the substrate 1.

As illustrated in FIG. 19B, the gate conductors 4 and the first mask layers 7 are formed on the substrate 1 via the gate insulators 3. The sidewall insulators 5 are then formed on the side faces of the gate conductors 4 and the first mask layers 7. In this way, the gate structures for the n-type transistors Trₙ₁ and Trₙ₂ and the p-type transistors Trₚ₁ and Trₚ₂ (not shown) are formed on the substrate 1.

Next, a resist mask (not shown) which has openings only in the regions of the n-type transistors Trₙ₁ and Trₙ₂ is formed on the substrate 1. As illustrated in FIG. 19C, the p⁺-type impurity regions 11 are formed in the substrate 1 by ion implantation using the resist mask. Using a similar method, the n⁺-type impurity regions 13 (not shown) are also formed in the substrate 1.

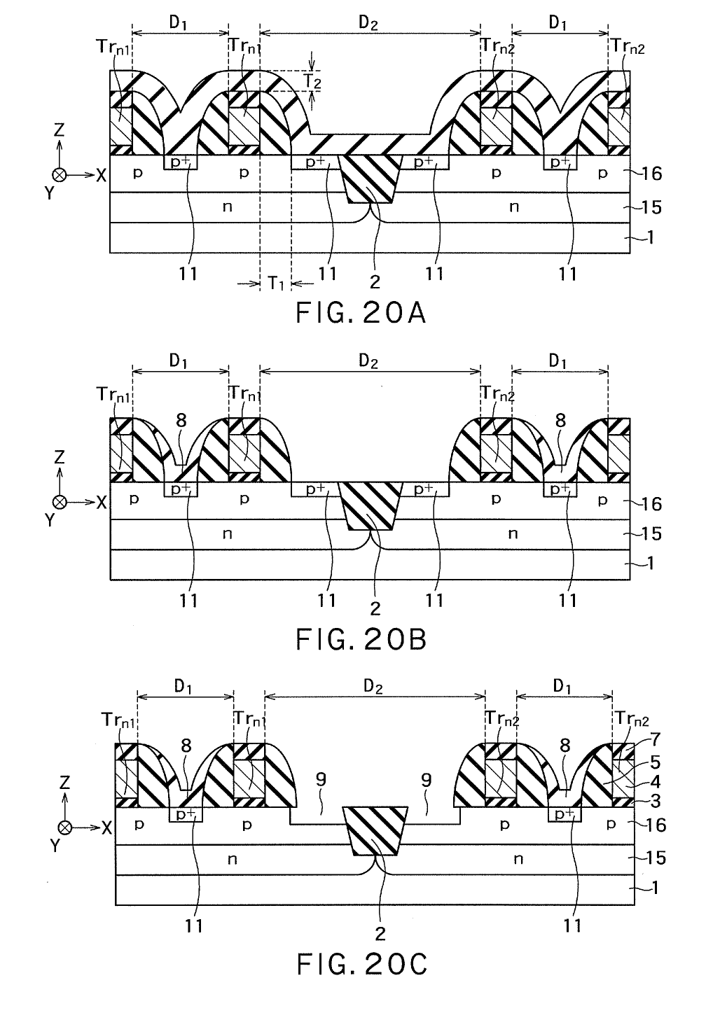

As illustrated in FIG. 20A, the second mask layer 8 is formed on the whole surface of the substrate 1. As a result, the n-type transistors Trₙ₁ and Trₙ₂, the p-type transistors Trₚ₁ and Trₚ₂ and the impurity regions 11 and 13 are covered with the second mask layer 8.

Sign T₁ designates a thickness of each sidewall insulator 5. Sign T₂ designates a thickness of the second mask layer 8. The thickness T₂ of the second mask layer 8 of the present embodiment is set so as to satisfy the conditions “D₁−2T₁<2T₂” and “D₂−2T₁>2T₂”. As a result, the regions of the first distance D₁ are closed with the second mask layer 8. The height of the upper face of the second mask layer 8 near the centers of the regions of the first distance D₁ is higher than the height of the upper face of the second mask layer 8 near the centers of the regions of the second distance D₂. In the present embodiment, in order to realize such closure, the first distance D₁ is set shorter than the second distance D₂.

As illustrated in FIG. 20B, the second mask layer 8 is etched back by RIE. In the present embodiment, the regions of the first distance D₁ are closed with the second mask layer 8. Therefore, the second mask layer 8 can be removed from the regions of the second distance D₂ while the second mask layer 8 is allowed to remain in the regions of the first distance D₁. In other words, the second mask layer 8 that covers only the regions of the first distance D₁ can be formed by not performing lithography.

As illustrated in FIG. 20C, the substrate 1 in the regions of the second distance D₂ is etched using the second mask layer 8 as a mask. As a result, the recesses 9 are formed in the substrate 1 in the regions of the second distance D₂, and the impurity regions 11 in the regions of the second distance D₂ are removed. Using a similar method, the impurity regions 13 (not shown) in the regions of the second distance D₂ are also removed.

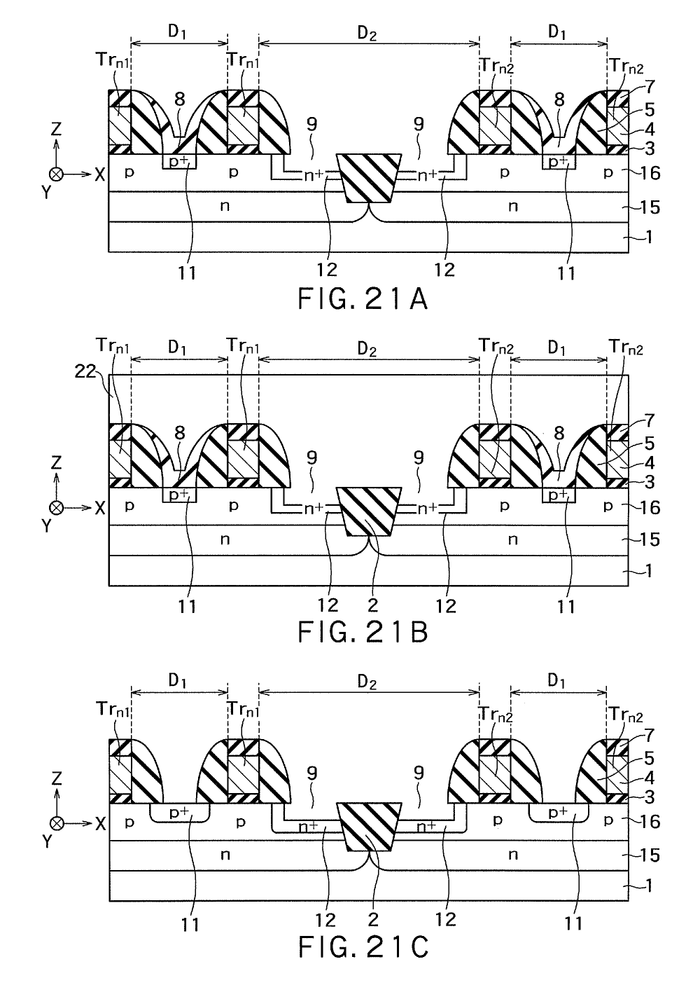

As illustrated in FIG. 21A, the resist mask 21 (not shown) which has openings only in the regions of the n-type transistors Trₙ₁ and Trₙ₂ is formed. The n⁺-type impurity regions 12 are formed in the substrate 1 by ion implantation using the second mask layer 8 and the resist mask 21.

As illustrated in FIG. 21B, the resist mask 22 which has openings only in the regions of the p-type transistors Trₚ₁ and Trₚ₂ is formed. The p⁺-type impurity regions 14 (not shown) are formed in the substrate 1 by ion implantation using the second mask layer 8 and the resist mask 22.

The activation annealing of the substrate 1 is then performed. As a result, the first source regions 11 and the first drain regions 12 are formed from the impurity regions 11 and 12 (FIG. 21C). Furthermore, the second source regions 13 and second drain regions 14 (not shown) are formed from the impurity regions 13 and 14 (not shown). As illustrated in FIG. 21C, the second mask layer 8 on the substrate 1 is then removed entirely.

Thereafter, inter layer dielectrics, contact plugs, via plugs, interconnect layers, passivation films and the like are formed on the substrate 1 to form interconnects for connecting the n-type transistors Trₙ₁ and Trₙ₂, the p-type transistors Trₚ₁ and Trₚ₂. In this way, the semiconductor device of the present embodiment is manufactured.

As described above, in the present embodiment, the finger structures are applied to the TFETs such that the first distance D₁ between the gate conductors 4 sandwiching the first source regions 11 and the second source regions 13 is set shorter than the second distance D₂ between the gate conductors 4 sandwiching the first drain regions 12 and the second drain regions 14 (D₁<D₂).

Therefore, the present embodiment makes it possible to reduce the circuit area in the case of using a TFET including the source region 11 or 13 and the drain region 12 or 14 which have different conductivity types, similarly to the first and second embodiments. In other words, the present embodiment makes it possible to attenuate the restriction of the gate length in the case of using the TFET.

The present embodiment can also be applied to the region R₂ of the NOR circuit in FIG. 12A as well as the region R₂ of the NAND circuit in FIG. 13A. Moreover, the structure of the region R₂ of the NAND circuit of the present embodiment may be used in combination with the structure of the region R₁ of the NAND circuit of the second modification of the first embodiment.

While certain embodiments have been described, these embodiments have, been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
one or more gate conductors provided above the substrate, and including a pair of first portions adjacent to each other and a pair of second portions adjacent to each other;
a first diffusion region which is provided in a first region located between the pair of first portions, and corresponds to one of a drain region of a first conductivity type and a source region of a second conductivity type for a first transistor of the first conductivity type; and
a second diffusion region which is provided in a second region located between the pair of second portions, and corresponds to the other of the drain and source regions for the first transistor,
wherein a first distance between the pair of first portions is shorter than a second distance between the pair of second portions.

2. The device of claim 1, wherein a difference between the first distance and the second distance is 20 nm or more.

3. The device of claim 1, wherein the pair of second portions are a gate electrode of the first transistor, and a gate electrode of a second transistor of the first conductivity type connected to the first transistor in series.

4. The device of claim 3, wherein the first and second transistors are a driver transistor and a transfer transistor of an SRAM.

5. The device of claim 1, wherein the pair of first portions are included in the same gate conductor.

6. The device of claim 5, wherein the pair of first portions are first and second gate electrode portions of the first transistor.

7. The device of claim 6, wherein the pair of second portions are the first or second gate electrode portion of the first transistor, and a first or second gate electrode portion of a second transistor of the first conductivity type.

8. The device of claim 7, wherein the second region includes:
the second diffusion region;
a third diffusion region having the same conductivity type as the second diffusion region, and corresponding to one of a drain region of the first conductivity type and a source region of the second conductivity type for the second transistor; and
an isolation region provided between the second and third diffusion regions.

9. A semiconductor device comprising:
a substrate;
one or more gate conductors provided above the substrate, and including a pair of first portions adjacent to each other;
a first diffusion region which is provided in a first region located between the pair of first portions, and corresponds to one of a drain region of a first conductivity type and a source region of a second conductivity type for a first transistor of the first conductivity type; and
a second diffusion region which is provided in a second region located opposite to the first region relative to one of the pair of first portions, and corresponds to the other of the drain and source regions for the first transistor,
wherein a first distance between the pair of first portions is shorter than a width of the second diffusion region in a direction parallel to the first distance.

10. The device of claim 9, wherein
the one of the pair of first portions is a gate electrode of the first transistor, and
the other of the pair of first portions is provided above an isolation region.

11. The device of claim 10, wherein the other of the pair of first portions which is provided above the isolation region is a dummy interconnect.

12. The device of claim 10, wherein the isolation region is located between the first diffusion region and a third diffusion region, the third diffusion region having the same conductivity type as the first diffusion region and corresponding to one of a drain region of the first conductivity type and a source region of the second conductivity type for a second transistor of the first conductivity type.

13. The device of claim 12, wherein the third diffusion region is provided between the other of the pair of first portions which is provided above the isolation region and a gate electrode of the second transistor.

14. The device of claim 12, wherein the first and second transistors are connected to each other in series.

15. A method of manufacturing a semiconductor device, comprising:
forming one or more gate conductors above a substrate, the one or more gate conductors including a pair of first portions adjacent to each other and a pair of second portions adjacent to each other;
implanting first impurities of first or second conductivity type in a first region between the pair of first portions and in a second region between the pair of second portions;
forming a mask layer above the first and second regions after the first impurities are implanted; and
implanting second impurities whose conductivity type is different from a conductivity type of the first impurities in the second region in a state where the mask layer is removed from the second region and covers the first region.

16. The method of claim 15, further comprising removing the mask layer from the first region after the second impurities are implanted.

17. The method of claim 15, wherein a first distance between the pair of first portions is shorter than a second distance between the pair of second portions.

18. The method of claim 17, wherein a difference between the first distance and the second distance is 20 nm or more.

19. The method of claim 17, wherein the mask layer is processed so as to be removed from the second region and to cover the first region by etching back the mask layer above the first and second regions.

20. The method of claim 15, wherein
one of a source region and a drain region is formed by using the first impurities, and
the other of the source region and the drain region is formed by using the second impurities.
